(19) United States
(12) Patent Application Publication
(10) Pub. No.: US 2025/0366314 A1
(43) Pub. Date: Nov. 27, 2025

(54) DISPLAY DEVICE, METHOD OF MANUFACTURING THE DISPLAY DEVICE, AND ELECTRONIC DEVICE COMPRISING THE DISPLAY DEVICE

(71) Applicant: Samsung Display Co., LTD., Yongin-si (KR)

(72) Inventors: Hyun Eok SHIN, Yongin-si (KR); Joon Yong PARK, Yongin-si (KR); Byung Soo SO, Yongin-si (KR); Su Kyoung YANG, Yongin-si (KR); Dong Min LEE, Yongin-si (KR); Keun Ho JANG, Yongin-si (KR)

(21) Appl. No.: 18/959,632

(22) Filed: Nov. 26, 2024

(30) Foreign Application Priority Data
May 21, 2024 (KR) 10-2024-0065571

(51) Int. Cl. H10K 59/122; H10K 50/828; H10K 59/12

(52) U.S. Cl. CPC H10K 59/122; H10K 50/828; H10K 59/1201

(57) ABSTRACT

According to an embodiment of the present disclosure, a display device, a method of manufacturing the display device, and an electronic device comprising the display device are provided. The display device includes a light emitting element disposed on a base layer and including an anode electrode, a cathode electrode, and a emission structure electrically connected to the anode electrode and the cathode electrode; a pixel definition layer covering a portion of the anode electrode; a sidewall disposed on the pixel definition layer and including a first sidewall and a second sidewall on the first sidewall; a conductive sidewall portion, wherein at least a portion of which the conductive sidewall portion is disposed on a side surface of the first sidewall and exposes the anode electrode; and a transparent conductive layer disposed on the cathode electrode and the conductive sidewall portion and including a transparent conductive material.

This application claims priority to Korean Patent Application No. 10-2024-0065571, filed on May 21, 2024, and all the benefits accruing therefrom under 35 U.S.C. § 119, the content of which in its entirety is herein incorporated by reference.

### BACKGROUND

### 1. Field

The present disclosure relates to a display device, a method of manufacturing the display device, and an electronic device comprising the display device.

### 2. Description of the Related Art

Recently, as interest in an information display is increasing, research and development of display devices is continuously being performed.

A display device may include a light emitting element and may include a plurality of layers disposed adjacent to each other to form a conductive structure.

In some cases, disposing the plurality of layers closely adjacent to each other may prevent a risk of lifting. For example when some of the plurality of layers are not closely adjacent to each other, a risk of lifting may occur, and a risk that impurities such as, for example, moisture are not properly blocked may occur.

### SUMMARY

The present disclosure is to provide a display device, a method of manufacturing the display device, and an electronic device comprising the display device in which light emitting elements and other components of the display device are closely sealed to prevent penetration of impurities such as, for example, moisture.

The present disclosure is to provide a display device, a method of manufacturing the display device, and an electronic device comprising the display device in which an electrical path for a signal applied to a light emitting element can be stably formed.

The present disclosure is to provide a display device, a method of manufacturing the display device, and an electronic device comprising the display device in which excellent adhesion between a light emitting element and layers adjacent thereto is provided, such that adjacent layers can be closely adjacent to each other.

According to an embodiment of the present disclosure, a display device includes a light emitting element disposed on a base layer and including an anode electrode, a cathode electrode, and a emission structure electrically connected to the anode electrode and the cathode electrode; a pixel definition layer covering a portion of the anode electrode; a sidewall disposed on the pixel definition layer and including a first sidewall and a second sidewall on the first sidewall; a conductive sidewall portion, wherein at least a portion of the conductive sidewall portion is disposed on a side surface of the first sidewall and exposes the anode electrode; and a transparent conductive layer disposed on the cathode electrode and the conductive sidewall portion and including a transparent conductive material.

According to an embodiment, the second sidewall may have a larger width than the first sidewall.

According to an embodiment, the conductive sidewall portion may entirely cover a side surface of the first sidewall and may have a smaller thickness than the second sidewall.

According to an embodiment, an end of the conductive sidewall portion and an end of the second sidewall may overlap each other when viewed in a plan view.

According to an embodiment, the cathode electrode may not expose the conductive sidewall portion on the first sidewall.

According to an embodiment, the cathode electrode may partially expose the conductive sidewall portion on the first sidewall.

According to an embodiment, the transparent conductive layer may entirely cover the conductive sidewall portion and the cathode electrode.

According to an embodiment, the cathode electrode may be electrically connected to the first sidewall.

According to an embodiment, the first sidewall may have larger electrical conductivity than the second sidewall.

According to an embodiment, the conductive sidewall portion and the second sidewall may include the same conductive material.

According to an embodiment, the first sidewall may include aluminum (Al). The second sidewall may include titanium (Ti). The conductive sidewall portion may include at least one of titanium (Ti), titanium nitride (TiN), molybdenum (Mo), and molybdenum alloy. The cathode electrode may include silver (Ag). The transparent conductive layer may include at least one of indium tin oxide (ITO), indium zinc oxide (IZO), indium oxide (IO), tin oxide (TO), indium gallium zinc oxide (IGZO), aluminum zinc oxide (AZO), aluminum tin oxide (ATO), indium tin zinc oxide (ITZO), zinc oxide (ZnO), and tin oxide (SnO2).

In some embodiments, the display device may further include a first sub-pixel area where light of a first color is provided; a second sub-pixel area where light of a second color is provided; and a third sub-pixel area where light of a third color is provided. The light emitting element may include a first light emitting element in the first sub-pixel area, a second light emitting element in the second sub-pixel area, and a third light emitting element in the third sub-pixel area.

A method of manufacturing a display device according to an embodiment of the present disclosure includes patterning an anode electrode on a base layer; patterning a sidewall including a first sidewall and a second sidewall on the first sidewall on the base layer; patterning a conductive sidewall portion covering a side surface of the first sidewall; patterning a emission structure on the anode electrode; patterning a cathode electrode that covers the conductive sidewall portion and is electrically connected to the emission structure; and patterning a transparent conductive layer covering the cathode electrode.

According to an embodiment, the patterning the conductive sidewall portion may include forming, based on a sputtering process, a base conductive sidewall portion that covers the anode electrode and the first sidewall; and performing an entire surface etching process on the base conductive sidewall portion and the second sidewall wherein performing the entire surface etching process provides the conductive sidewall portion.

According to an embodiment, the entire surface etching process may include an anisotropic dry etching process.

According to an embodiment, the patterning the cathode electrode may include forming an electrode layer based on a sputtering process. The patterning the transparent conductive layer may include patterning a conductive layer based on a second sputtering process.

According to an embodiment, the patterning the conductive sidewall portion may be such that the conductive sidewall portion entirely covers a side surface of the first sidewall. The patterning the transparent conductive layer may be such that the transparent conductive layer entirely covers the cathode electrode.

According to an embodiment, the first sidewall may include aluminum (Al). The second sidewall may include titanium (Ti). The conductive sidewall portion may include at least one of titanium (Ti), titanium nitride (TiN), molybdenum (Mo), and molybdenum alloy. The cathode electrode may include silver (Ag). The transparent conductive layer may include at least one of indium tin oxide (ITO), indium zinc oxide (IZO), indium oxide (IO), tin oxide (TO), indium gallium zinc oxide (IGZO), aluminum zinc oxide (AZO), aluminum tin oxide (ATO), indium tin zinc oxide (ITZO), zinc oxide (ZnO), and tin oxide (SnO2).

According to an embodiment, the manufacturing method may further include, before the patterning the sidewall, patterning a pixel definition layer partially covering the anode electrode on the base layer. The patterning the pixel definition layer may include exposing the anode electrode.

According to an embodiment, the manufacturing method may further include, before the patterning the sidewall, forming a base pixel definition layer partially covering the anode electrode on the base layer, and after the patterning the conductive sidewall portion, etching the base pixel definition layer, wherein etching the base pixel definition layer patterns a pixel definition layer exposing the anode electrode.

According to an embodiment of the present disclosure, an electronic device may comprise: a processor configured to provide input image data; a display device configured to display an image based on the input image data, the display device including sub-pixel areas; and a power supply configured to supply power to the display device. The display device includes a light emitting element disposed on a base layer and including an anode electrode, a cathode electrode, and a emission structure electrically connected to the anode electrode and the cathode electrode; a pixel definition layer covering a portion of the anode electrode; a sidewall disposed on the pixel definition layer and including a first sidewall and a second sidewall on the first sidewall; a conductive sidewall portion, wherein at least a portion of the conductive sidewall portion is disposed on a side surface of the first sidewall and exposes the anode electrode; and a transparent conductive layer disposed on the cathode electrode and the conductive sidewall portion and including a transparent conductive material.

According to an embodiment of the present disclosure, a display device, a method of manufacturing the display device, and an electronic device comprising the display device can be provided in which light emitting elements and other components of the display device are closely sealed to prevent penetration of impurities such as, for example, moisture.

According to an embodiment of the present disclosure, a display device, a method of manufacturing the display device, and an electronic device comprising the display device can be provided in which an electrical path for a signal applied to a light emitting element can be stably formed.

According to an embodiment of the present disclosure, a display device, a method of manufacturing the display device, and an electronic device comprising the display device can be provided in which excellent adhesion between a light emitting element and layers adjacent thereto is provided, such that adjacent layers can be closely adjacent to each other.

### BRIEF DESCRIPTION OF THE DRAWINGS

FIG. 1 is a schematic plan view illustrating a display device according to an embodiment.

FIGS. 2 and 4 are schematic cross-sectional views illustrating a display device according to an embodiment.

FIG. 3 is a schematic enlarged view of an EA1 area in FIG. 2.

FIG. 5 is a schematic enlarged view of an EA2 area in FIG. 4.

FIG. 6 is a schematic cross-sectional view illustrating a light emitting element according to an embodiment.

FIGS. 7 to 16 are schematic cross-sectional views illustrating each process step of a method of manufacturing a display device according to an embodiment.

FIG. 17 is a schematic block diagram illustrating an electronic device including a display device in accordance with an embodiment.

FIG. 18 is a schematic diagram illustrating an example where the electronic device of FIG. 17 is implemented as a smartphone.

FIG. 19 is a schematic diagram illustrating an example where the electronic device of FIG. 17 is implemented as a tablet computer.

### DETAILED DESCRIPTION

It will be apparent to those skilled in the art that various modifications and variations can be made in the present disclosure without departing from the spirit or scope of the disclosure, and specific example embodiments are described in the drawings and explained in the detailed description. Thus, it is intended that the present invention covers the modifications and variations of this invention provided they come within the scope of the present invention and their equivalents.

The terms, ‘first’, ‘second’ and the like may be simply used for description of various constituent elements, but those meanings may not be limited to the restricted meanings. The above terms are used for distinguishing one constituent element from other constituent elements. For example, a first constituent element may be referred to as a second constituent element and similarly, the second constituent element may be referred to as the first constituent element within the scope of the appended claims. Descriptions explaining the singular, unless explicitly described to the contrary, may be interpreted as the plural meaning.

In the specification, the word “comprise” or “has” is used to specify existence of a feature, a numbers, a process, an operation, a constituent element, a part, or a combination thereof, and it will be understood that existence or additional possibility of one or more other features or numbers, processes, operations, constituent elements, parts, or combinations thereof are not excluded in advance. In some aspects, it will be understood that when an element such as, for example, a layer, film, area, or substrate is referred to as being “on” another element, it can be directly on the other element or intervening elements may also be present. In the specification, it will be understood that when an element such as, for example, a layer, film, area, or substrate is referred to as being disposed “on” another element, the disposed direction is not limited to an upper direction and include a side portion direction or a lower direction. In contrast, It will be understood that when an element such as, for example, a layer, film, area, or substrate is referred to as being “beneath” another element, it can be directly beneath the other element or intervening elements may also be present.

The present disclosure relates to a display device, a method of manufacturing the display device, and an electronic device comprising the display device. Hereinafter, a display device, a method of manufacturing the display device, and an electronic device comprising the display device according to embodiments will be described with reference to the accompanying drawings.

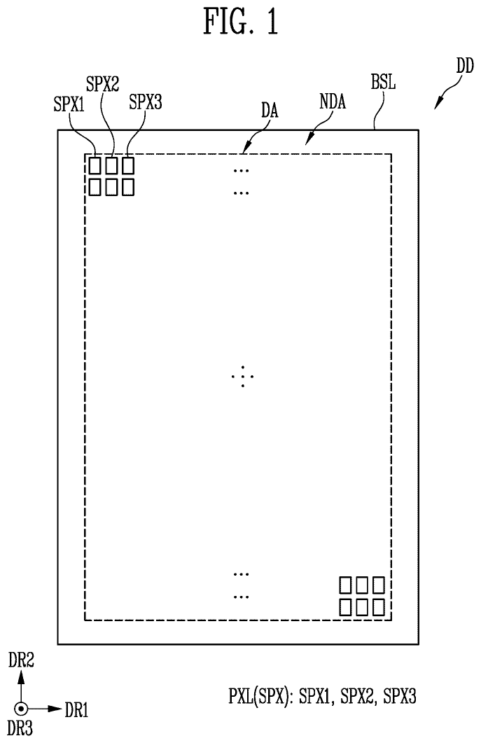

FIG. 1 is a schematic plan view illustrating a display device according to an embodiment.

Referring to FIG. 1, the display device DD may include a base layer BSL and a pixel PXL disposed on the base layer BSL. The display device DD may further include a driving circuit unit (e.g., a scan driver and a data driver) for driving the pixel PXL, lines, and pads.

The display device DD (or base layer BSL) may include a display area DA and a non-display area NDA. The non-display area NDA may refer to an area other than the display area DA. The non-display area NDA may surround at least a portion of the display area DA.

The base layer BSL may form a base surface of the display device DD. According to an embodiment, the base layer BSL may be a lower substrate for disposing layers forming the display device DD. The base layer BSL may be a rigid or flexible substrate or film. For example, the base layer BSL may include a glass material. Alternatively, the base layer BSL may include a silicon material. Alternatively, the base layer BSL may include polyimide. However, embodiments of the present disclosure are not limited thereto.

The plane defined in this specification may be a direction extending in the first direction DR1 and the second direction DR2 and may be defined based on a plane on which the base layer BSL is disposed. According to an embodiment, the third direction DR3 may be a thickness direction of the base layer BSL, and the third direction DR3 may be a light exit direction of the display device DD.

The display area DA may mean an area in which the pixels PXL are disposed. The non-display area NDA may mean an area in which the pixel PXL is not disposed. A driving circuit unit, wires, and pads connected to the pixel PXL of the display area DA may be disposed in the non-display area NDA.

According to an embodiment, the pixel PXL (or sub-pixels SPX) may be arranged according to a stripe or PENTILE™ array structure, but embodiments of the present disclosure are not limited thereto, and various embodiments may be provided in the present disclosure.

According to an embodiment, the pixel PXL (or sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be sub-pixels. At least one first sub-pixel SPX1, second sub-pixel SPX2, and third sub-pixel SPX3 may form a pixel unit configured to emit light of various colors.

Each of the first sub-pixel SPX, the second sub-pixel SPX, and the third sub-pixel SPX may emit light of a color.

For example, the first sub-pixel SPX1 may be a red pixel that emits red light (e.g., first color), the second sub-pixel SPX2 may be a green pixel that emits green light (e.g., second color), and the third sub-pixel SPX3 may be a blue pixel that emits blue light (e.g., third color). The red pixel may provide light in a wavelength range of 600 nm to 750 nm. The green pixel may provide light in a wavelength band of 480 nm to 560 nm. The blue pixel may provide light in a wavelength band of 370 nm to 460 nm.

According to an embodiment, the number of second sub-pixels SPX2 may be greater than the number of first and third sub-pixels SPX1 and SPX3. However, the color, type, and/or number of the first sub-pixel SPX1, the second sub-pixel SPX2, and the third sub-pixel SPX3 forming each pixel unit are not limited to specific examples.

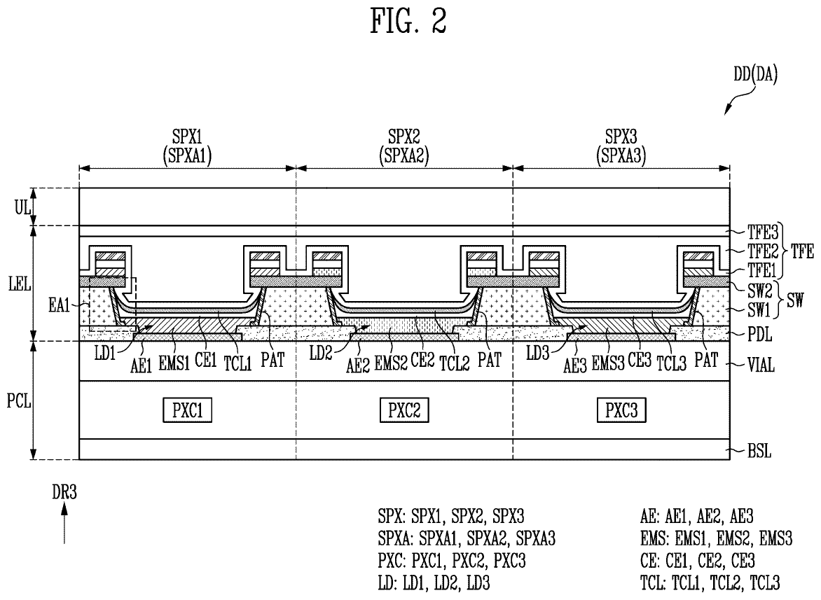

With reference to FIGS. 2 to 6, a display device DD according to an embodiment will be described.

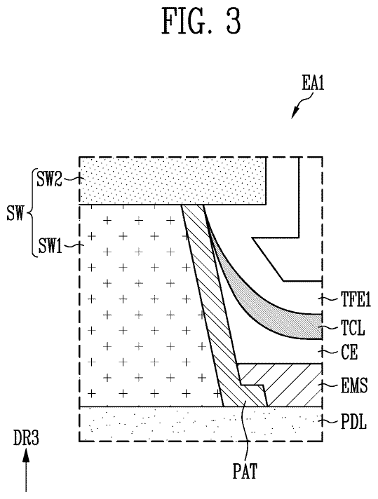

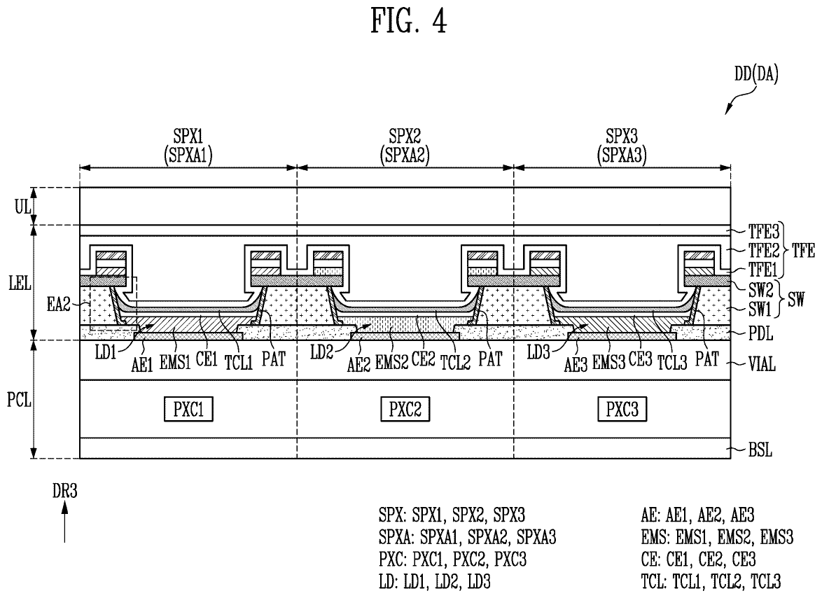

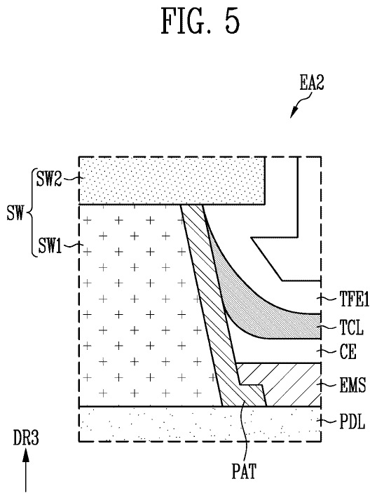

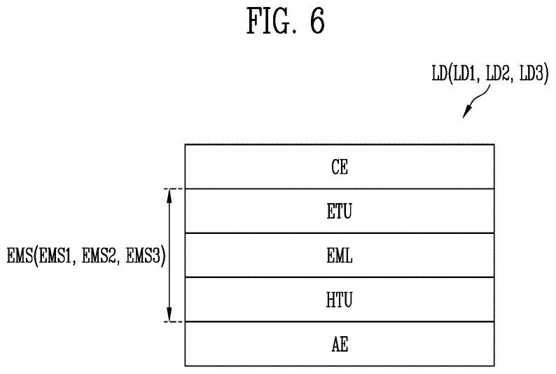

FIGS. 2 and 4 are schematic cross-sectional views illustrating a display device according to an embodiment. FIG. 3 is a schematic enlarged view of an EA1 area in FIG. 2. FIG. 5 is a schematic enlarged view of an EA2 area in FIG. 4. FIGS. 2 and 3 show the display device DD according to the first embodiment, and FIGS. 4 and 5 show the display device DD according to the second embodiment. The detailed structure of FIG. 2 will be clearly understood in conjunction with FIG. 3. The detailed structure of FIG. 4 will be clearly understood in conjunction with FIG. 5. FIG. 6 is a schematic cross-sectional view illustrating a light emitting element according to an embodiment.

Referring to FIGS. 2 to 6, the display device DD according to an embodiment may include a pixel-circuit layer PCL, a light-emitting-element layer LEL on the pixel-circuit layer PCL, and an upper layer UL on the light-emitting-element layer LEL, and may include a sub-pixel SPX corresponding to the sub-pixel area SPXA.

According to an embodiment, the sub-pixels SPX may form the sub-pixel area SPXA. The sub-pixel area SPXA may be an area where light of a color is visible. For example, the sub-pixel area SPXA1 may include a first sub-pixel area SPXA1 formed by the first sub-pixel SPX1 and where light of a first color is provided (e.g., where light of the first color is visible), a second sub-pixel area SPXA2 formed by the second sub-pixel SPX2 and where light of a second color is provided (e.g., where light of the second color is visible), and a third sub-pixel area SPXA3 formed by a third sub-pixel SPX3 and where light of a third color is provided (e.g., where light of the third color is visible).

The pixel-circuit layer PCL may include a base layer BSL, pixel circuits PXC, and a via layer VIAL. According to an embodiment, the pixel-circuit layer PCL may be referred to as a backplane layer.

The base layer BSL may form a base on which the pixel circuit PXC configured to drive the light emitting element LD is disposed. According to an embodiment, the light emitting element LD may be an organic light emitting diode.

The pixel circuit PXC may be disposed on the base layer BSL and may be configured to drive the light emitting element LD. The pixel-circuit layer PCL may include conductive layers and insulating layers, and the conductive layers may form the pixel circuit PXC. The pixel circuit PXC may be included in the corresponding sub-pixel SPX. For example, the pixel circuit PXC may include a first pixel circuit PXC1 in the first sub-pixel area SPXA1, a second pixel circuit PXC2 in the second sub-pixel area SPXA2, and a third pixel circuit PXC3 in the third sub-pixel area SPXA3.

The via layer VIA may be formed on the pixel-circuit layer PCL and may cover the pixel circuit PXC. The via layer VIA may be a planarization layer and may be a layer in which a contact portion that electrically connects the pixel circuit PXC and the anode electrode AE is formed. The via layer VIA may include various organic materials. However, embodiments of the present disclosure are not limited thereto.

The light-emitting-element layer LEL may be disposed on the pixel-circuit layer PCL. The light-emitting-element layer LEL may include an anode electrode AE, a pixel definition layer PDL, a sidewall SW, a conductive sidewall portion PAT, a emission structure EMS, a cathode electrode CE, and a transparent conductive layer TCL, and an encapsulation layer TFE.

The anode electrode AE may be disposed on the pixel-circuit layer PCL (e.g., via layer VIAL). The anode electrode AE may be electrically connected to the pixel circuit PXC through a contact portion penetrating the via layer VIAL. The anode electrode AE may include a first anode electrode AE1 disposed in the first sub-pixel area SPXA1, a second anode electrode AE2 disposed in the second sub-pixel area SPXA2, and a third anode electrode AE3 disposed in the third sub-pixel area SPXA3.

The anode electrode AE may include various conductive materials. For example, the anode electrodes AE may include a transparent conductive material. For example, the anode electrodes AE may include at least one of transparent conductive materials such as, for example, indium tin oxide (ITO), indium zinc oxide (IZO), zinc oxide (ZnOx), indium gallium zinc oxide (IGZO), or indium tin zinc oxide (ITZO). The anode electrodes AE may include an opaque conductive material that can reflect light. For example, the anode electrodes AE may include at least one selected from the group consisting of titanium nitride (TiN), silver (Ag), and aluminum (Al).

The pixel definition layer PDL may cover the anode electrode AE and may be disposed on the pixel-circuit layer PCL (e.g., via layer VIAL). The pixel definition layer PDL may expose at least a portion of the anode electrode AE.

The pixel definition layer PDL may include organic or inorganic materials. For example, the pixel definition layer PDL may include a plurality of layers each containing an inorganic material. However, embodiments of the present disclosure are not limited thereto.

The sidewall SW may be disposed on the pixel definition layer PDL. The sidewall SW may be disposed in a boundary area between the sub-pixel areas SPXA. The sidewall SW may be disposed between the first to third emission structures EMS1 to EMS3 that are adjacent to each other.

The sidewall SW may include a first sidewall SW1 on the pixel definition layer PDL and a second sidewall SW2 on the first sidewall SW1. The first sidewall SW1 may form a base on which the second sidewall SW2 is disposed. The second sidewall SW2 may have a larger width than the first sidewall SW1, and thus may form a tip that protrudes in a direction of a plane where the substrate SUB is disposed. For example, at least a portion of the second sidewall SW2 may not overlap the first sidewall SW1 when viewed in a plan view. The second sidewall SW2 may entirely cover the first sidewall SW1 when viewed in a plan view.

The first sidewall SW1 and the second sidewall SW2 may include a conductive material. According to an embodiment, the first sidewall SW1 and the second sidewall SW2 may include different conductive materials. For example, the first sidewall SW1 may have larger electrical conductivity than the second sidewall SW2. The second sidewall SW2 may have characteristics that are more robust to an etching environment than the first sidewall SW1. For example, the first sidewall SW1 may include aluminum (Al), and the second sidewall SW2 may include titanium (Ti). However, embodiments of the present disclosure are not limited thereto.

The conductive sidewall portion PAT may be disposed on the first sidewall SW1 and, according to an embodiment, may cover a portion of the pixel definition layer PDL. The conductive sidewall portion PAT may expose the anode electrode AE.

The conductive sidewall portion PAT may be disposed under the second sidewall SW2. The conductive sidewall portion PAT may cover a side surface of the first sidewall SW1. According to an embodiment, the conductive sidewall portion PAT may entirely cover the side surface of the first sidewall SW1. The conductive sidewall portion PAT may not expose the side surface of the first sidewall SW1. For example, the conductive sidewall PAT may be patterned based on a sputtering process, and the conductive sidewall PAT may entirely cover the side surface of the first sidewall SW1.

The conductive sidewall portion PAT may include a conductive material. The conductive sidewall portion PAT may be electrically connected to the first sidewall SW1. A portion of a cathode path may be formed in the conductive sidewall portion PAT. For example, the conductive sidewall portion PAT may include a conductive material which is suitable for a dry etching process and is with a relatively reduced risk of a formation of an oxide layer. For example, the conductive sidewall portion PAT may include at least one of titanium (Ti), titanium nitride (TiN), molybdenum (Mo), and molybdenum alloy.

According to an embodiment, the conductive sidewall portion PAT may include the same conductive material as the second sidewall PW2. For example, the conductive sidewall portion PAT may include titanium (Ti), as may the second sidewall PW2.

The conductive sidewall portion PAT may be disposed in each of the first to third sub-pixel areas SPXA1 to SPXA3. For example, the conductive sidewall portion PAT may be formed on each of the sidewalls SW in an area adjacent to the light emitting elements LD.

The conductive sidewall portion PAT may have a relatively small thickness. For example, the conductive sidewall portion PAT may have a smaller thickness (e.g., in the third direction DR3) than the second sidewall SW2.

According to an embodiment, the conductive sidewall portion PAT may closely adhere the cathode electrode CE to the sidewall SW. In an example in which the first sidewall SW1 includes aluminum, an aluminum oxide layer may be formed on a portion of an outer surface of the first sidewall SW1 during a manufacturing process of the display device DD. In this case, experimentally, it may be difficult to closely adhere the cathode electrode CE to the first sidewall SW1 due to the aluminum oxide layer. However, according to an embodiment, the conductive sidewall portion PAT having a relatively small thickness may be disposed on the first sidewall SW1 such that the electrical conductivity characteristics of the first sidewall SW1 are relatively maintained, while the conductive sidewall portion PAT is interposed between the first sidewall SW1 and the cathode electrode CE to improve the adhesion of the cathode electrode CE. Accordingly, for example, a risk of delamination between layers can be reduced, and the structural stability of the display device DD can be improved.

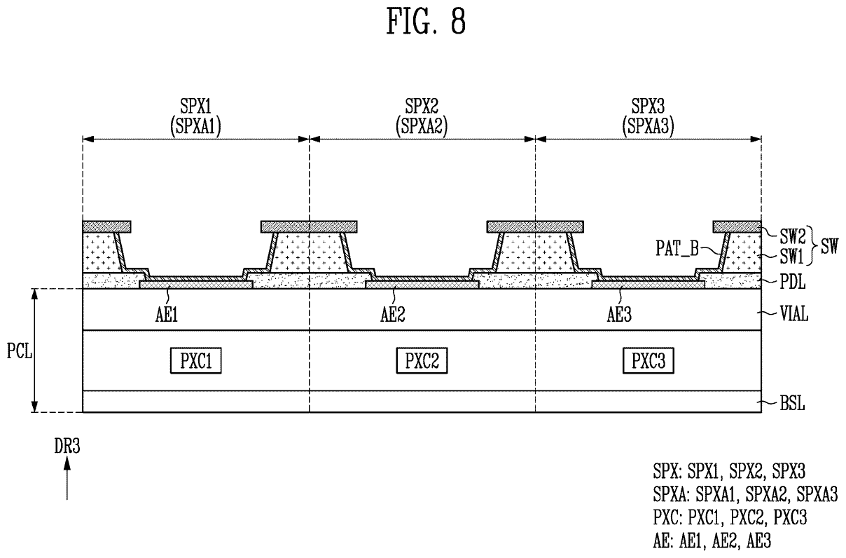

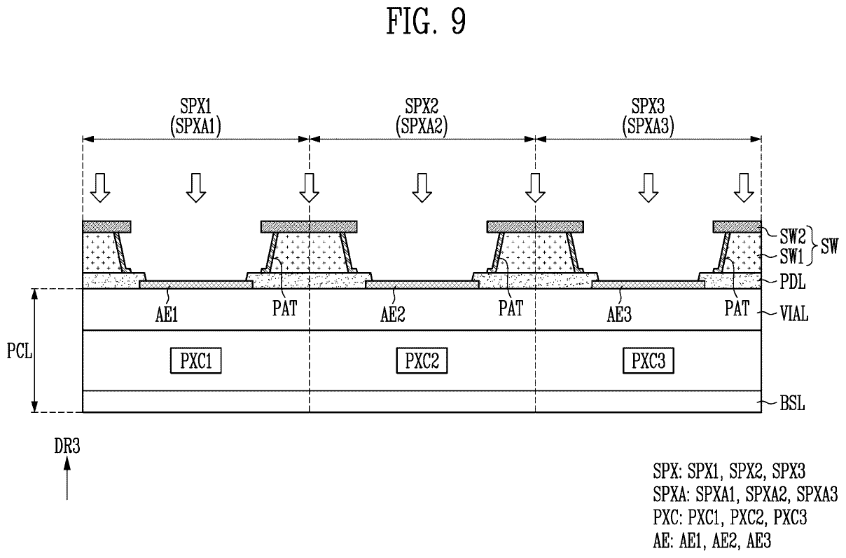

An end of the conductive sidewall portion PAT and an end of the second sidewall SW2 may overlap each other, for example, in a plan view. In an example in which an etching process for patterning the conductive sidewall portion PAT is performed, the conductive structure corresponding to the position of the conductive sidewall portion PAT may not be etched by the second sidewall SW2. Accordingly, for example, the method may be implemented without excessive processing procedures such as, for example, additional masks, and process convenience may be improved. Related details will be described later with reference to drawings such as FIGS. 8 and 9.

The emission structure EMS may be disposed between the anode electrode AE and the cathode electrode CE, a surface of the emission structure EMS may be electrically connected to the anode electrode AE, and the other surface of the emission structure EMS may be electrically connected to the cathode electrode CE. At least a portion of the emission structure EMS may cover the conductive sidewall portion PAT.

The emission structure EMS may include a first emission structure EMS1 configured to emit light of a first color, a second emission structure EMS2 configured to emit light of a second color, and a third emission structure EMS3 configured to emit light of a third color.

The emission structure EMS may include multiple layers. For example, the emission structure EMS may include a hole transport unit HTU, a light emitting unit EML (or light generating layer), and an electron transport unit ETU. Each layer forming the emission structure EMS may include an organic material, and according to an embodiment, the emission structure EMS may further include a metal-containing compound or an inorganic material such as, for example, quantum dots.

The hole transport unit HTU may include a multilayer structure having a plurality of layers each including different materials. For example, the hole transport unit HTU may include a hole injection layer and a hole transport layer, and according to an embodiment, the hole transport unit HTU may further include a light emitting auxiliary layer, an electron blocking layer, and the like.

The light emitting unit EML may include a material capable of emitting light of a color. The light emitting unit EML may include a host and a dopant. The host of the light emitting unit EML may be a light emitting material that can capture carriers (electrons and holes) for generating light, and may induce the efficient generation of excitons. The dopant may include a phosphorescent dopant or a fluorescent dopant. According to an embodiment, examples of dopants are not particularly limited thereto. According to an embodiment, the dopant may include an organic material or a metal complex.

The electron transport unit ETU may include a multilayer structure having a plurality of layers each including different materials. The electron transport unit ETU may include an electron injection layer and an electron transport layer, and according to an embodiment, the electron transport unit ETU may further include an electron buffer layer, a hole blocking layer, and the like.

The cathode electrode CE may be disposed on the emission structure EMS and the conductive sidewall portion PAT. The cathode electrode CE may be deposited on the base layer BSL, and when the deposition process is performed, at least a portion of the cathode electrode CE may be cut off at the boundary area between the sub-pixel areas SPXA by the second sidewall SW2.

According to an embodiment, the cathode electrode CE may include a first cathode electrode CE1 included in the first sub-pixel SP1, a second cathode electrode CE2 included in the second sub-pixel SP2, and a third cathode electrode CE3 included in the third sub-pixel SP3.

According to an embodiment, the cathode electrode CE may receive a cathode signal (e.g., cathode voltage) through the sidewall SW (e.g., the first sidewall SW1) and the conductive sidewall portion PAT. For example, although not illustrated in the drawing, the sidewall SW may be electrically connected to a power line formed in the pixel-circuit layer PCL through a contact member penetrating the pixel definition layer PDL.

The cathode electrode CE may include various conductive materials. For example, the cathode electrode CE may be a conductive thin film including silver (Ag). For example, the cathode electrode CE may include silver (Ag) and may further include additional metals. The additional metals may include at least one of magnesium (Mg), aluminum (Al), copper (Cu), calcium (Ca), and barium (Ba). For example, the cathode electrode CE may include a silver-magnesium (AgMg) alloy. However, embodiments of the present disclosure are not limited thereto.

According to an embodiment (see FIGS. 2 and 3), the cathode electrode CE may entirely cover the conductive sidewall portion PAT. For example, in the area between the sidewalls SW, an end of the cathode electrode CE may be formed in an area corresponding to the height of the first sidewall SW1. The end of the cathode electrode CE may be defined (e.g., formed) directly under the second sidewall SW2. The cathode electrode CE may not expose the conductive sidewall portion PAT. In this case, the cathode electrode CE can be stably electrically connected to the first sidewall SW1 through the conductive sidewall portion PAT, and a cathode electrical path with relatively low contact resistance can be closely defined.

However, embodiments of the present disclosure are not limited thereto. In another embodiment (see FIGS. 4 and 5), the cathode electrode CE may cover a portion of the conductive sidewall portion PAT but may not cover another portion of the conductive sidewall portion PAT. For example, in the area between the sidewalls SW, the end of the cathode electrode CE may be formed at a lower height than the height of the first sidewall SW1. The end of the cathode electrode CE may be defined (e.g., formed) to be spaced apart from the second sidewall SW2. The cathode electrode CE may expose a portion of the conductive sidewall portion PAT.

The first anode electrode AE1, the first emission structure EMS1, and the first cathode electrode CE1 may form a first light emitting element LD1 configured to emit light of a first color, the second anode electrode AE2, the second emission structure EMS2, and the second cathode electrode CE2 may form a second light emitting element LD2 configured to emit light of a second color, and the third anode electrode AE3, the third emission structure EMS3, and the third cathode electrode CE3 may form a third light emitting element LD3 configured to emit light of a third color.

The transparent conductive layer TCL may be disposed on the cathode electrode CE. The transparent conductive layer TCL may be deposited on the base layer BSL, and when the deposition process is performed, at least a portion of the transparent conductive layer TCL may be cut off at the boundary area between the sub-pixel areas SPXA by the second sidewall SW2.

The transparent conductive layer TCL may include a first transparent conductive layer TCL1 included in the first sub-pixel SP1, a second transparent conductive layer TCL2 included in the second sub-pixel SP2, and a third transparent conductive layer TCL3 included in the third sub-pixel SP3.

The transparent conductive layer TCL may include a transparent conductive material. The transparent conductive material may include at least one of indium tin oxide (ITO), indium zinc oxide (IZO), indium oxide (IO), tin oxide (TO), indium gallium zinc oxide (IGZO), aluminum zinc oxide (AZO), aluminum tin oxide (ATO), indium tin zinc oxide (ITZO), zinc oxide (ZnO), and tin oxide (SnO2). However, embodiments of the present disclosure are not limited thereto.

The transparent conductive layer TCL may entirely cover the conductive sidewall portion PAT. The transparent conductive layer TCL may entirely cover the cathode electrode CE on the conductive sidewall portion PAT. An end of the transparent conductive layer TCL may be defined (e.g., formed) directly under the second sidewall SW2. The transparent conductive layer TCL may not expose the conductive sidewall portion PAT and the cathode electrode CE. In this case, the transparent conductive layer TCL may compensate for the relatively low adhesive strength of the cathode electrode CE. For example, the transparent conductive layer TCL may entirely cover an upper surface of the cathode electrode CE, so the encapsulation layer TFE can be closely formed on the cathode electrode CE. That is, the encapsulation layer TFE can be directly adjacent to the lower layers, and the risk of the layers peeling off from each other can be reduced, so the encapsulation layer TFE can closely seal the lower layers. Accordingly, for example, the risk of external impurities such as, for example, moisture penetrating into the light emitting elements LD can be reduced.

According to an embodiment (see FIGS. 2 and 3), the transparent conductive layer TCL may be spaced apart from the conductive sidewall portion PAT. Alternatively, in another embodiment (see FIGS. 4 and 5), the transparent conductive layer TCL may contact a portion of the conductive sidewall portion PAT exposed by the cathode electrode CE.

According to an embodiment, at least a portion of each of materials formed in the same process as the first to third emission structures EMS1 to EMS3, materials formed in the same process as the cathode electrode CE, and materials formed in the same process as the transparent conductive layer TCL, may be disposed on the second sidewall SW2.

The encapsulation layer TFE can seal the light emitting element LD and can offset steps formed by layers formed under the encapsulation layer TFE. The encapsulation layer TFE may include a multilayer structure. For example, the encapsulation layer TFE may include first to third encapsulation layers TFE3. According to an embodiment, the first encapsulation layer TFE1 may include an inorganic layer, the second encapsulation layer TFE2 may include an organic layer, and the third encapsulation layer TFE3 may include an inorganic layer. The first encapsulation layer TFE1 may passivate the light emitting elements LD, the transparent conductive layer TCL, and the sidewalls SW, and the second and third encapsulation layers TFE2 and TFE3 may be disposed sequentially on the first encapsulation layer TFE1. According to an embodiment, the encapsulation layer TFE may be a thin film encapsulation film.

The upper layer UL may be disposed on the light-emitting-element layer LEL based on a display direction (e.g., third direction DR3) of the display device DD. The upper layer UL may include various functional layers. For example, the upper layer UL may include first to third color filters formed in each of the first to third sub-pixel areas SPXA to SPXA3 and transmitting light of the first to third colors, respectively. The upper layer UL may include a cover window and/or other components of the display device dd. The structure of the upper layer UL is not particularly limited.

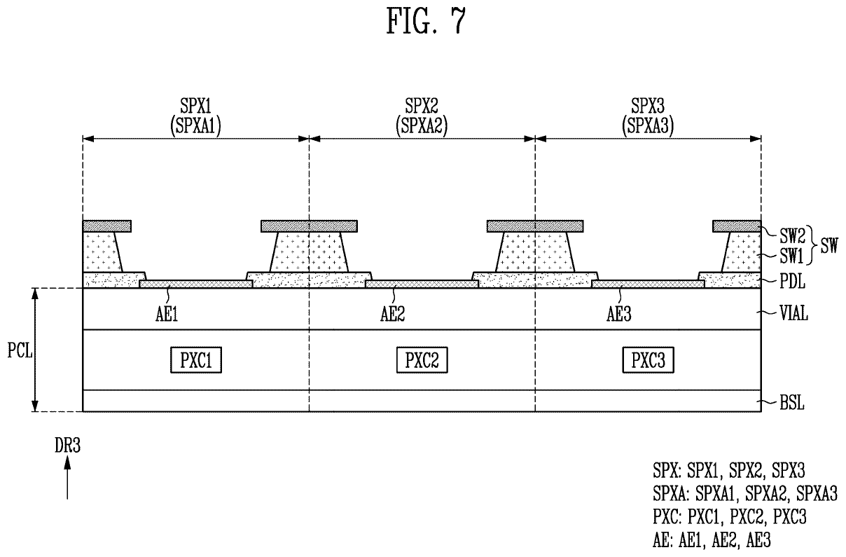

With reference to FIGS. 7 to 16, a method of manufacturing the display device DD according to an embodiment will be described. Duplicate description is briefly explained or not repeated.

FIGS. 7 to 16 are schematic cross-sectional views illustrating each process step of a method of manufacturing a display device according to an embodiment. For convenience of description, FIGS. 7 to 16 are illustrated based on the cross-sectional structure described herein with reference to FIGS. 2 and 4.

FIGS. 7 to 16 illustrate process steps in which each layer of the pixel-circuit layer PCL and the light-emitting-element layer (LEL) is formed in the manufacturing process of the display device DD in accordance with one or more embodiments of the present disclosure.

First, with reference to FIGS. 7 to 12, a method of manufacturing the display device DD according to an embodiment will be described.

Referring to FIG. 7, the method may include providing the pixel-circuit layer PCL, and the method may include patterning the anode electrode AE, the pixel definition layer PDL, and the sidewall SW on the pixel-circuit layer PCL.

According to an embodiment, the method may include forming the conductive layer or insulating layer on the base layer (BSL) based on a typical process for manufacturing a semiconductor device. For example, the method may include forming the conductive layer or insulating layer on the base layer BSL by a photolithography process, etching the conductive layer or insulating layer by various methods (wet etching, dry etching, or the like), and depositing the conductive layer or insulating layer by various methods (sputtering, chemical vapor deposition method, or the like). The present disclosure is not necessarily limited to specific examples described herein.

The method may include patterning the first to third pixel circuits PXC1 to PXC3 on the base layer BSL, and the method may include forming the via layer VIAL covering the first to third pixel circuits PXC1 to PXC3 on the base layer BSL.

The method may include, in the first to third sub-pixel areas SPXA1 to SPXA3, patterning the first to third anode electrodes AE1 to AE3 and patterning the pixel definition layer PDL partially covering the first to third anode electrodes AE1 to AE3 respectively.

The method may include patterning the first sidewall SW1 and the second sidewall SW2 on the pixel definition layer PDL. The first sidewall SW1 may include a tapered side surface, and the second sidewall SW1 may form a protruding portion on the first sidewall SW1.

Referring to FIG. 8, the method may include patterning the base conductive sidewall portion PAT_B.

The method may include depositing the base conductive sidewall portion PAT_B such that the base conductive sidewall portion PAT_B covers a side surface of the first sidewall SW1 and the anode electrodes AE. According to an embodiment, the method may include forming the base conductive sidewall portion PAT_B based on a sputtering process. In this case, compared to the case where the thermal deposition process is applied, the base conductive sidewall portion PAT_B may entirely cover the side surface of the first sidewall SW1.

In some aspects, the base conductive sidewall portion PAT_B may cover a portion of the anode electrode AE exposed by the pixel definition layer PDL. A portion of the base conductive sidewall portion PAT_B may not overlap the second sidewall SW2 when viewed in a plan view.

Referring to FIG. 9, the method may include etching at least a portion of the base conductive sidewall portion PAT_B, and the etching may provide a conductive sidewall portion PAT.

The method may include performing an entire surface etching process on the base conductive sidewall portion PAT_B and the second sidewall SW2. The entire surface etching process may include surface etching respective exposed surfaces of the base conductive sidewall portion PAT_B and the second sidewall SW2. The entire surface etching process applied in this step may be an anisotropic dry etching process. According to an embodiment, the etching process may partially reduce the thickness of the second sidewall SW2, and when viewed in a plan view, remove a portion of the base conductive sidewall portion PAT_B that does not overlap (e.g., is not covered by) the second sidewall SW2.), and when viewed in a plan view, and expose the anode electrode AE in an area of the anode electrode AE that does not overlap (e.g., is not covered by) the second sidewall SW2.

The method may include etching the base conductive sidewall portion PAT_B based on the anisotropic dry etching process, in which the ends of each of the manufactured conductive sidewall portion PAT_B and the second sidewall SW2 are defined (e.g., formed) such that the ends overlap each other. In some aspects, the base conductive sidewall portion PAT_B may include the same conductive material (e.g., titanium (Ti)) as the second sidewall SW2, and accordingly, for example, the method may include patterning the conductive sidewall portion PAT_B based on the thickness relationship between the base conductive sidewall portion PAT_B and the second sidewall SW2. Accordingly, for example, since the method may be implemented without a separate photo mask, the process steps can be simplified, and improved process convenience with respect to the process of etching the base conductive sidewall portion PAT_B can be provided.

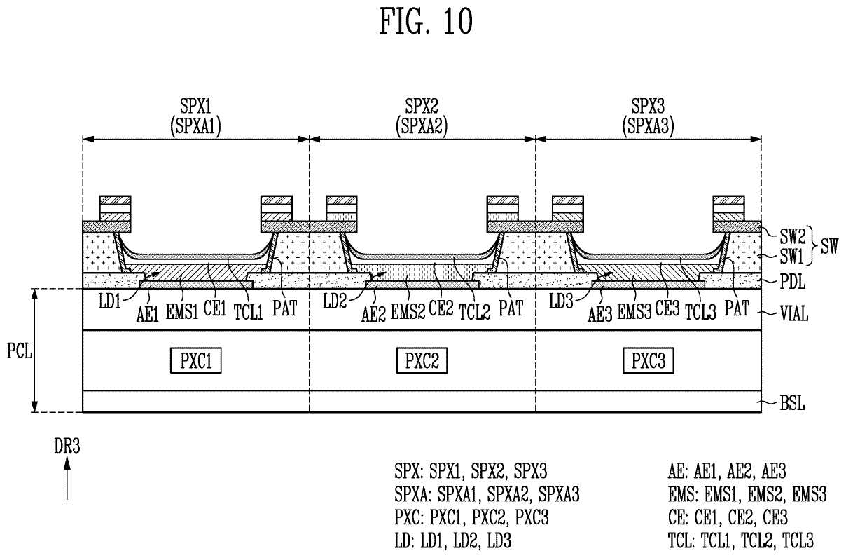

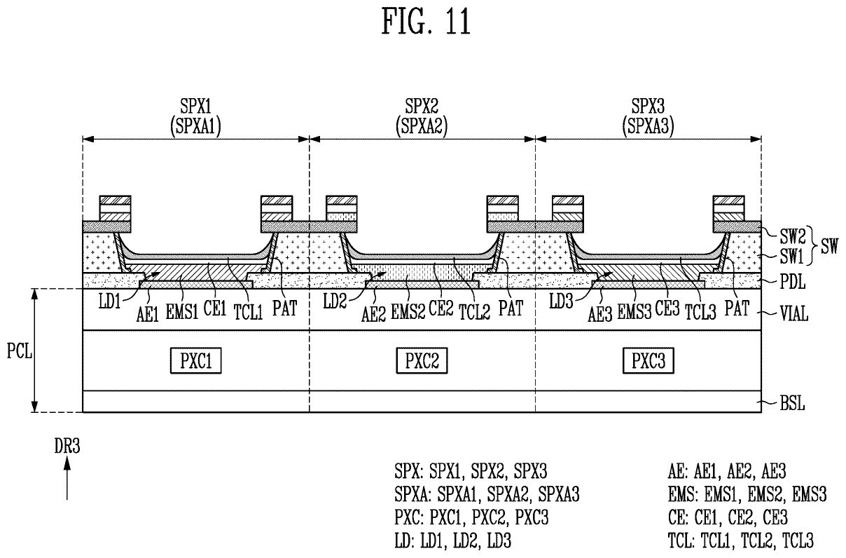

Referring to FIGS. 10 and 11, the method may include sequentially patterning first to third emission structures EMS1 to EMS3 on the first to third anode electrodes AE1 to AE3, respectively, patterning the first to third cathode electrodes CE1 to CE3, and patterning the first to third transparent conductive layers TCL1 to TCL3.

The method may include patterning each of the first to third emission structures EMS1 to EMS3 based on a deposition process. For example, the method may include depositing each of the first to third emission structures EMS1 to EMS3 using a fine metal mask (FMM). However, embodiments of the present disclosure are not limited thereto.

The method may include depositing an electrode layer for patterning the first to third cathode electrodes CE1 to CE3. According to an embodiment, the method may include forming the first to third cathode electrodes CE1 to CE3 based on a sputtering process.

In this case, compared to the case where the thermal deposition process is applied, the first to third cathode electrodes CE1 to CE3 can adequately cover the conductive sidewall portion PAT on the side surface of the first sidewall SW1 as a whole (see FIG. 10). However, embodiments of the present disclosure are not limited thereto. For example (see FIG. 11), the method may include patterning the first to third cathode electrodes CE1 to CE3 based on a sputtering process, performing the sputtering process such that the ends of the first to third cathode electrodes CE1 to CE3 are defined at a relatively low height, and patterning the first to third cathode electrodes CE1 to CE3 in association with exposing the conductive sidewall portion PAT.

The method may include depositing a conductive layer for patterning the first to third transparent conductive layers (TCL1 to TCL3). According to an embodiment, the method may include forming the first to third transparent conductive layers TCL1 to TCL3 based on the sputtering process. In this case, compared to the case where the thermal deposition process is applied, the first to third transparent conductive layers TCL1 to TCL3 may cover the conductive sidewall portion PAT and the cathode electrodes CE on the side surface of the first sidewall SW1 as a whole.

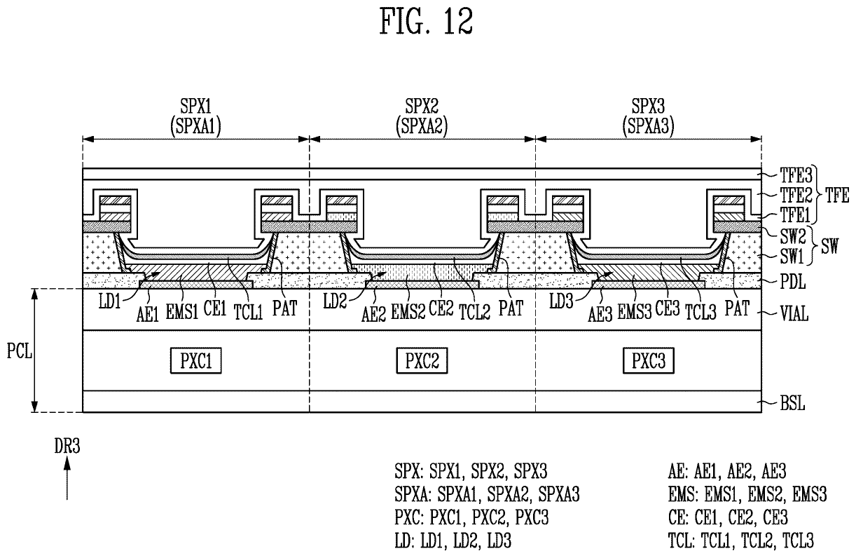

Referring to FIG. 12, the method may include forming an encapsulation layer TFE covering the light emitting element LD, the transparent conductive layer TCL, and the sidewall SW.

The method may include forming the first to third encapsulation layers TFE1 to TFE3 sequentially. Accordingly, for example, the lower layers of the encapsulation layer TFE may be suitably encapsulated.

Thereafter, according to an embodiment, the method may include forming the upper layer UL including various functional layers on the encapsulation layer TFE, thus providing the display device DD according to an embodiment.

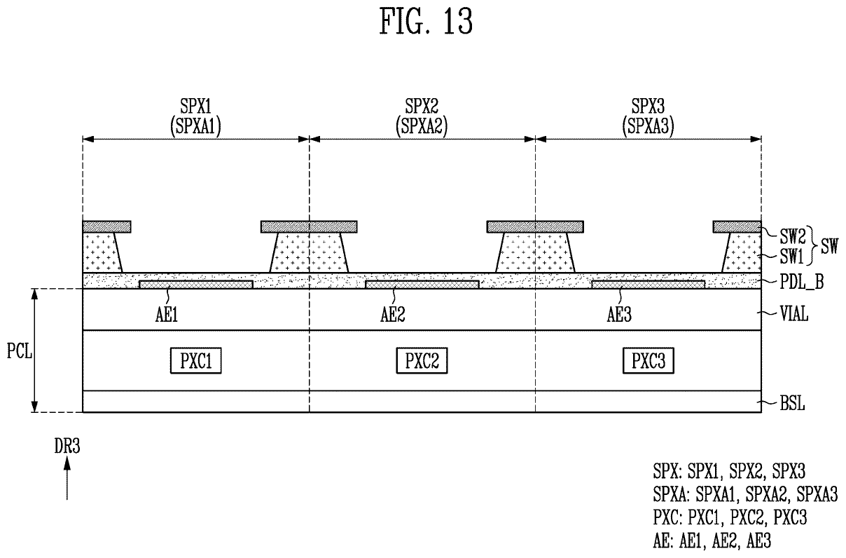

Next, with reference to FIGS. 13 to 16, a method of manufacturing the display device DD according to a partially modified embodiment will be described. Duplicate description is briefly explained or not repeated.

The method of manufacturing the display device DD illustrated in FIGS. 13 to 16 may include aspects of the method of manufacturing the display device DD as described herein with reference to FIGS. 7 to 12, and repeated descriptions of like elements are omitted for brevity.

The method of manufacturing the display device DD illustrated in FIGS. 13 to 16 may be different from the method of manufacturing the display device DD described herein with reference to FIGS. 7 to 12, in that the pixel definition layer PDL may expose the anode electrode AE after the conductive sidewall portion PAT is patterned.

For example, referring to FIG. 13, the method may include forming a base pixel definition layer PDL_B covering the anode electrodes AE before patterning the sidewall SW, and in this step, the anode electrodes AE may not be exposed.

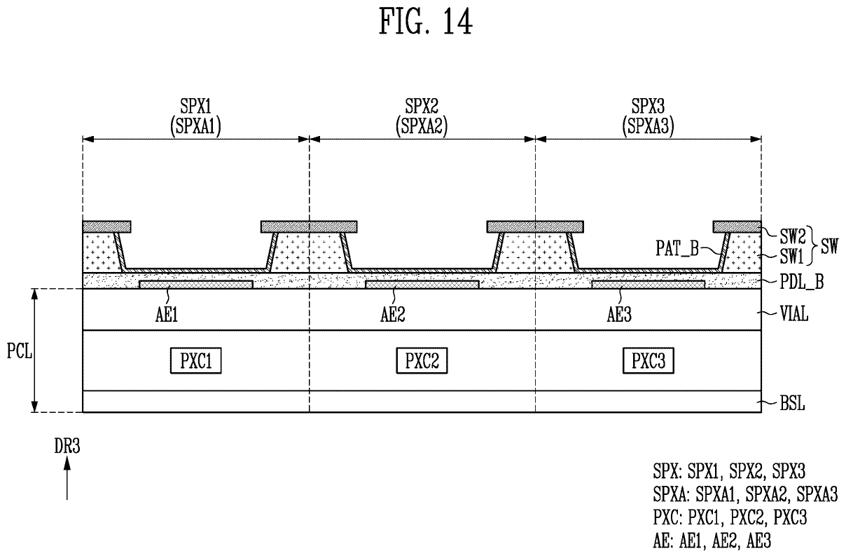

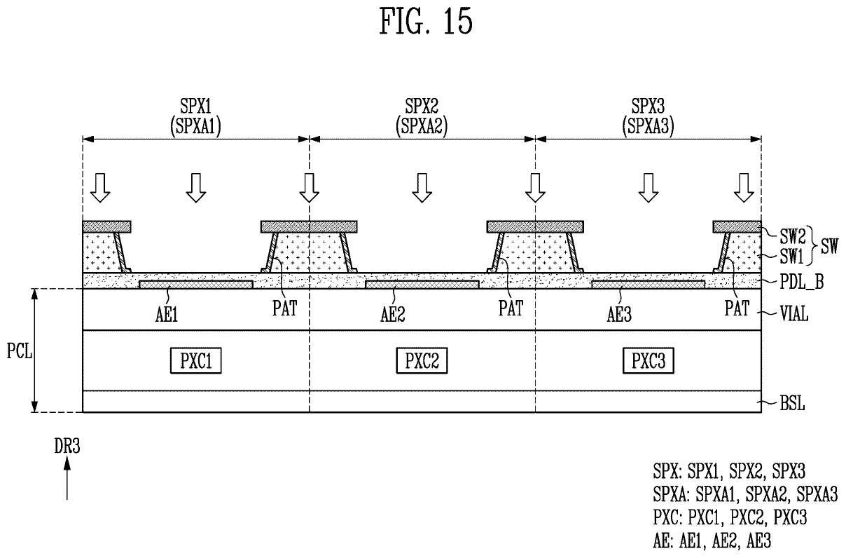

Referring to FIG. 14, when the base pixel definition layer PDL_B does not expose the anode electrodes AE, the base conductive sidewall portion PAT_B may be formed. For example, FIG. 14 illustrates a case in which the base pixel definition layer PDL_B does not expose the anode electrodes AE, and the method may include forming the base conductive sidewall portion PAT_B. Referring to FIG. 15, when the base pixel definition layer PDL_B does not expose the anode electrodes AE, the base conductive sidewall portion PAT_B may be etched to pattern the conductive sidewall portion PAT. For example, FIG. 15 illustrates a case in which the base pixel definition layer PDL_B does not expose the anode electrodes AE, and the method may include patterning the conductive sidewall portion PAT by etching the base conductive sidewall portion PAT_B.

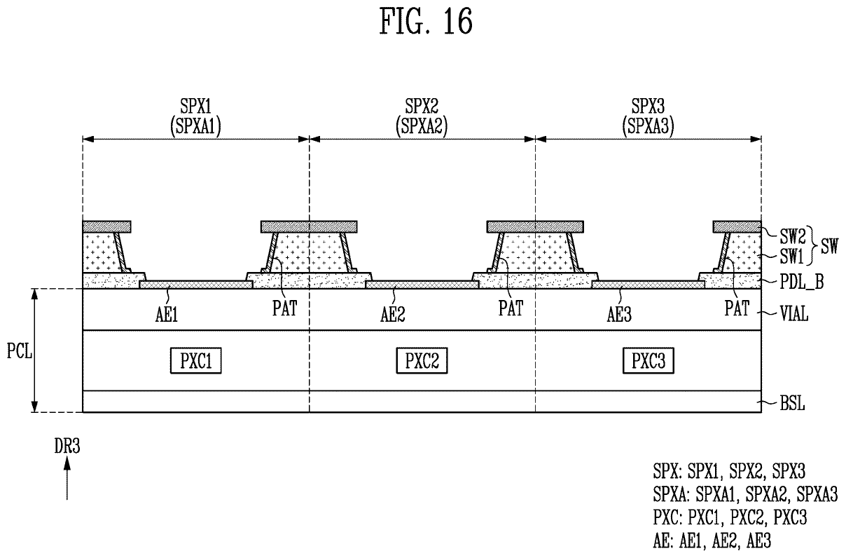

Referring to FIG. 16, the method may include, after the conductive sidewall portion PAT is patterned, etching the base pixel definition layer PDL_B, patterning the pixel definition layer PDL, and exposing the anode electrode AE. According to this embodiment, after the base pixel definition layer PDL_B is etched, the anode electrode AE may be exposed, so damage to the anode electrode AE can be more closely prevented.

Thereafter, as described herein with reference to FIGS. 10 to 12, the method may include sequentially forming the layers forming the light-emitting-element layer LEL, and further, disposing the upper layer UL on the light-emitting-element layer LEL to provide the display device DD according to an embodiment.

Hereinafter, an electronic device 1000 including the display device DD in accordance with an embodiment will be described.

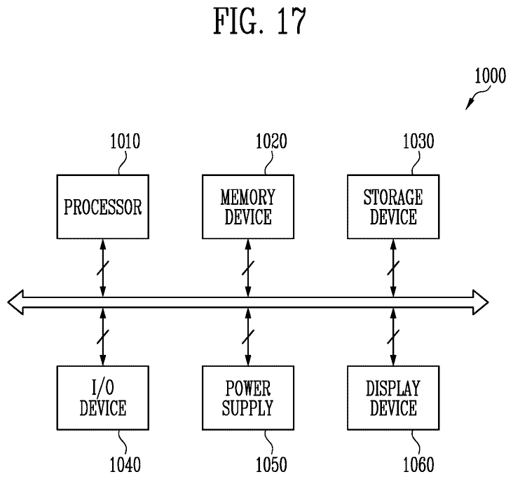

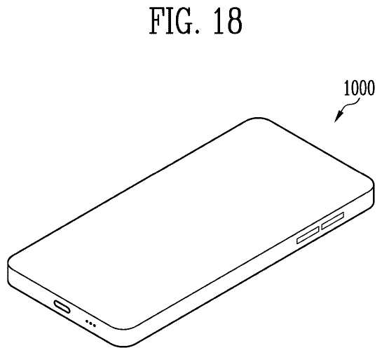

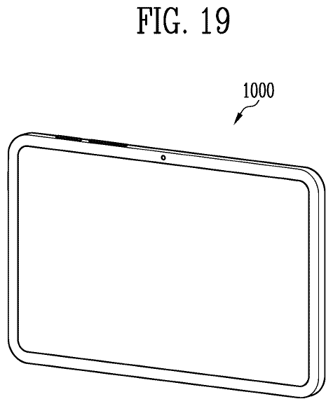

FIG. 17 is a schematic block diagram illustrating an electronic device 1000 including a display device in accordance with an embodiment. FIG. 18 is a schematic diagram illustrating an example where the electronic device 1000 of FIG. 17 is implemented as a smartphone. FIG. 19 is a schematic diagram illustrating an example where the electronic device 1000 of FIG. 17 is implemented as a tablet computer.

Referring to FIGS. 17 to 19, the electronic device 1000 may include a processor 1010, a memory device 1020, a storage device 1030, an input/output (I/O) device 1040, a power supply 1050, and a display device 1060. The display device 1060 may be the display device DD of FIG. 1. The electronic device 1000 may further include various ports for communication with a video card, a sound card, a memory card, a USB device, or other systems. In an embodiment, as illustrated in FIG. 18, the electronic device 1000 may be a smartphone. In an embodiment, as illustrated in FIG. 19, the electronic device 1000 may be a tablet computer. However, the aforementioned examples are illustrative, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may include at least one of a central processing unit, an application processor, a graphic processing unit, a communication processor, an image signal processor, a controller, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to image data signals and/or control signals from the processor 1010. The display device 1060 may be connected to other components through the buses or other communication links.

In the descriptions of the methods and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

As described herein, while the present disclosure has been illustrated and described with reference to certain embodiments thereof, it will be understood by those skilled in the art that various changes in forms and details may be made therein without departing from the spirit and scope of the present disclosure as defined by the appended claims and their equivalents.

Accordingly, the technical scope of the present disclosure may be determined by on the technical scope of the accompanying claims.

What is claimed is:

1. A display device comprising:
a light emitting element disposed on a base layer and comprising an anode electrode, a cathode electrode, and a emission structure electrically connected to the anode electrode and the cathode electrode;
a pixel definition layer covering a portion of the anode electrode;
a sidewall disposed on the pixel definition layer and comprising a first sidewall and a second sidewall on the first sidewall;
a conductive sidewall portion, wherein at least a portion of the conductive sidewall portion is disposed on a side surface of the first sidewall and exposes the anode electrode; and
a transparent conductive layer disposed on the cathode electrode and the conductive sidewall portion and comprising a transparent conductive material.

2. The display device of claim 1, wherein the second sidewall has a larger width than the first sidewall.

3. The display device of claim 1, wherein the conductive sidewall portion entirely covers the side surface of the first sidewall and has a smaller thickness than the second sidewall.

4. The display device of claim 1, wherein an end of the conductive sidewall portion and an end of the second sidewall overlap each other when viewed in a plan view.

5. The display device of claim 1, wherein the cathode electrode does not expose the conductive sidewall portion on the first sidewall.

6. The display device of claim 1, wherein the cathode electrode partially exposes the conductive sidewall portion on the first sidewall.

7. The display device of claim 1, wherein the transparent conductive layer entirely covers the conductive sidewall portion and the cathode electrode.

8. The display device of claim 1, wherein the cathode electrode is electrically connected to the first sidewall.

9. The display device of claim 1, wherein the first sidewall has a larger electrical conductivity than the second sidewall.

10. The display device of claim 9, wherein the conductive sidewall portion and the second sidewall comprise the same conductive material.

11. The display device of claim 1, wherein:
the first sidewall comprises aluminum (AI),
the second sidewall comprises titanium (Ti),
the conductive sidewall portion comprises at least one of titanium (Ti), titanium nitride (TiN), molybdenum (Mo), and molybdenum alloy,
the cathode electrode comprises silver (Ag), and
the transparent conductive layer comprises at least one of indium tin oxide (ITO), indium zinc oxide (IZO), indium oxide (IO), tin oxide (TO), indium gallium zinc oxide (IGZO), aluminum zinc oxide (AZO), aluminum tin oxide (ATO), indium tin zinc oxide (ITZO), zinc oxide (ZnO), and tin oxide (SnO2).

12. The display device of claim 1, further comprising:
a first sub-pixel area where light of a first color is provided;
a second sub-pixel area where light of a second color is provided; and
a third sub-pixel area where light of a third color is provided,
wherein the light emitting element comprises a first light emitting element in the first sub-pixel area, a second light emitting element in the second sub-pixel area, and a third light emitting element in the third sub-pixel area.

13. A method of manufacturing a display device, the method comprising:
patterning an anode electrode on a base layer;
patterning a sidewall comprising a first sidewall and a second sidewall on the first sidewall on the base layer;
patterning a conductive sidewall portion covering a side surface of the first sidewall;
patterning a emission structure on the anode electrode;
patterning a cathode electrode that covers the conductive sidewall portion and is electrically connected to the emission structure; and
patterning a transparent conductive layer covering the cathode electrode.

14. The method of claim 13, wherein the patterning the conductive sidewall portion comprises:
forming, based on a sputtering process, a base conductive sidewall portion that covers the anode electrode and the first sidewall; and
performing an entire surface etching process on the base conductive sidewall portion and the second sidewall, wherein performing the entire surface etching process provides the conductive sidewall portion.

15. The method of claim 14, wherein the entire surface etching process comprises an anisotropic dry etching process.

16. The method of claim 13, wherein:
the patterning the cathode electrode comprises forming an electrode layer based on a sputtering process, and
the patterning the transparent conductive layer comprises patterning a conductive layer based on a second sputtering process.

17. The method of claim 16, wherein:
the patterning the conductive sidewall portion is such that the conductive sidewall portion entirely covers a side surface of the first sidewall, and
the patterning the transparent conductive layer is such that the transparent conductive layer entirely covers the cathode electrode.

18. The method of claim 13, wherein:
the first sidewall comprises aluminum (AI),
the second sidewall comprises titanium (Ti),
the conductive sidewall portion comprises at least one of titanium (Ti), titanium nitride (TIN), molybdenum (Mo), and molybdenum alloy,
the cathode electrode comprises silver (Ag), and
the transparent conductive layer comprises at least one of indium tin oxide (ITO), indium zinc oxide (IZO), indium oxide (IO), tin oxide (TO), indium gallium zinc oxide (IGZO), aluminum zinc oxide (AZO), aluminum tin oxide (ATO), indium tin zinc oxide (ITZO), zinc oxide (ZnO), and tin oxide (SnO2).

19. The method of claim 13, further comprising, before the patterning the sidewall, patterning a pixel definition layer partially covering the anode electrode on the base layer,
wherein the patterning the pixel definition layer comprises exposing the anode electrode.

20. The method of claim 13, further comprising:
before the patterning the sidewall, forming a base pixel definition layer partially covering the anode electrode on the base layer; and
after the patterning the conductive sidewall portion, etching the base pixel definition layer, wherein etching the base pixel definition layer patterns a pixel definition layer exposing the anode electrode.

21. An electronic device, comprising:
a processor configured to provide input image data;
a display device configured to display an image based on the input image data, the display device including sub-pixel areas; and
a power supply configured to supply power to the display device,
wherein the display device comprises:
a light emitting element disposed on a base layer and comprising an anode electrode, a cathode electrode, and a emission structure electrically connected to the anode electrode and the cathode electrode;
a pixel definition layer covering a portion of the anode electrode;
a sidewall disposed on the pixel definition layer and comprising a first sidewall and a second sidewall on the first sidewall;
a conductive sidewall portion, wherein at least a portion of the conductive sidewall portion is disposed on a side surface of the first sidewall and exposes the anode electrode; and
a transparent conductive layer disposed on the cathode electrode and the conductive sidewall portion and comprising a transparent conductive material.
